(19) United States
(12) Patent Application Publication
(10) Pub. No.: US 2009/0206319 A1
(43) Pub. Date: Aug. 20, 2009

(54) SEMICONDUCTOR DEVICE FOR GENERATING AN OSCILLATING VOLTAGE

(75) Inventors: Neil John Pilgrim, Aberdeen (GB); Geoffrey Martin Dunn, Aberdeen (GB); Ata-Ul-Hebib Kahlid, Glasglow (GB); Colin Roy Stanley, Glasglow (GB); Iain Granger Thayne, Glasgow (GB); David Robert Sime Cumming, Glasgow (GB)

Correspondence Address: Studebaker & Brackett PC, 1890 Preston White Drive, Suite 105, Reston, VA, 20191, US

(73) Assignees: ABERDEEN UNIVERSITY - RESEARCH AND INNOVATION, Aberdeen (GB); UNIVERSITY COURT OF THE UNIVERSITY OF GLASGOW, Glasgow (GB)

(21) Appl. No.: 12/298,813

(22) PCT Filed: Apr. 30, 2007
(86) PCT No.: PCT/GB2007/001568

§ 371 Date: Feb. 2, 2009

(30) Foreign Application Priority Data
Apr. 28, 2006 (GB) 0608515.3

(51) Int. Cl. H01L 47/02; H01L 47/00

(52) U.S. Cl. 257/6; 438/604; 257/E47.004; 257/E47.005

(57) ABSTRACT

A semiconductor device which displays an oscillating voltage due to the creation of charge domains which includes a plurality of semiconductor layers and at least two electrodes spaced from one another in the direction of the layers, an upper of which has a composition and/or dimensions predetermined so that a charge therein balances a depletion from a surface charge of the upper layer on application of a potential difference across said electrodes. The electrodes may be in contact solely with the upper layer. A method of manufacturing the device is also provided.

The present invention relates to a semiconductor device for generating an oscillating voltage by means of negative differential resistivity (NDR).

NDR may be provided, for example, by transferred electron effects such as the Gunn, effect or real-space electron transfer.

Most Gunn effect diodes are constructed in a “vertical” layered configuration, with contacts at top and bottom and electron conduction through, and substantially perpendicular to, the semiconductor interfaces. Devices with this type of structure are described in U.S. Pat. No. 4,801,982, U.S. Pat. No. 5,250,815, U.S. Pat. No. 5,258,624, and U.S. Pat. No. 5,675,157.

This device geometry has disadvantages associated with the heating of the device by the current in use. Electron densities much greater than 1×10¹⁶ cm⁻³ are generally not possible in such devices because of overheating, and this provides a lower limit of about 1 μm to the device length, below which a Gunn domain will not have room to form and transfer effectively. This in turn sets an upper limit to the frequency of operation of about 90 GHz for fundamental mode operation.

In practice, most such vertical devices are longer than 1 μm, and designed to operate at about half this frequency. If higher frequencies are desired, power is extracted by second harmonic operation, which is relatively inefficient.

The possibility of horizontal Gunn effect device architectures has been explored in the past, such a configuration being particularly well suited to monolithic integration. One such device is the Field-effect controlled transferred electron device “FECTED” of Thim described in U.S. Pat. No. 3,740,666. This device is designed to operate in transit-time independent mode by exploiting the negative differential resistivity (NDR) of a domain trapped under the gate electrode of the device.

Other authors have at various times commented on the possibility of Gunn instabilities forming in FET (field effect transistor) and HEMT (high electron mobility transistor) structures. For example, the Monte-Carlo simulation studies of Glisson, Hauser et al. (J. Appl. Phys. Vol 51, p 5445-5449 (1980)) have shown how it might be possible to generate negative differential resistivity in GaAs-AlGaAs layered lattice-matched quantum-well hetero-structures with an electric field applied parallel to the layered hetero-junction interfaces. This mechanism has been termed “real-space electron transfer”, since it involves the physical transfer of electrons from a high mobility (i.e. low effective mass) GaAs region to an adjacent lower mobility higher band gap AlGaAs region as the applied electric field intensity is increased. Thus the electrons are physically transferred between layers in real space, rather than being transferred to “heavy carrier” satellite bands in k-space, as with the conventional Gunn effect.

Devices using this type of hetero-structure were proposed in 1979 in U.S. Pat. No. 4,257,055 by Hess et al., and in U.S. Pat. No. 4,903,092 by Luryi et al. However, such devices are not known to have been successfully fabricated.

According to one aspect of the present invention, there is provided a semiconductor device comprising at least a first and a second electrode and a plurality of semiconductor layers, said layers being arranged substantially parallel to one another with adjacent layers comprising different semiconductor materials so that the device produces voltage oscillations due to a negative differential resistivity on application of a potential difference across said electrodes, said electrodes being attached to said device spaced from one another in a direction parallel to said layers, said device further comprising an upper semiconductor layer wherein a composition and/or dimension of said upper layer is chosen so that a charge therein balances a depletion from a surface charge of the upper layer on application of said potential difference.

It has been found that the charge due to surface effects can have a significant impact on the creation of domains. It has been hypothesised that negative charges may become trapped at the surface which causes depletion of the layers involved in the creation of a negative differential resistivity and therefore impede the creation of domains, deleteriously influencing the operation of the device. Therefore, the composition of the upper layer is chosen so that any accumulation of surface charge during use can be counteracted.

The amount of surface charge which accumulates will depend on the composition of the device as a whole and on the operating conditions (such as the magnitude of the potential difference applied between the electrodes). Therefore, the composition and or dimensions of the upper layer may depend on the manner in which the device is used.

The chosen composition of the upper layer may relate to the choice of semiconductor material from which said upper layer is composed.

Preferably, the material of said upper layer is chosen so that it resists oxidation as oxidation can impede the performance of the device over time.

The chosen composition of the upper layer may relate to the degree or manner of doping of the upper layer. It has been found that if the upper layer has more charge than is needed to counteract the surface charge (e.g. is over doped with an n-type doping), then this layer is not fully depleted during operation of the device and therefore has excess mobile charge which can disrupt the device operation. It has been hypothesised that this is due to the excessive doping providing an alternate route for current flow along, as opposed to across, the device layers, which impedes the formation of domains.

For a certain type and doping of semiconductor material the amount of charge therein will depend on the layer height and it is preferable that the height and composition of the upper layer are both engineered to ensure that this layer acts to counterbalance the surface charge during operation of the device.

Preferably, the upper layer is composed of n-GaAs.

Alternatively, the upper layer may be composed of a plurality of sub-layers of differing doping levels, said sub-layers being disposed so that a lower doped layer is closer to a surface of the device than a higher doped layer.

The upper layer may be inactive in that it does not contribute or receive charge carriers in the formation of said negative differential resistivity.

Preferably, the composition and/or height of said upper semiconductor layer is chosen so that an electrostatic potential through said layers of said device is substantially flat.

A composition of said semiconductor layers may be chosen so that, on application of said potential difference, domains spanning more than one layer form in said device, said voltage oscillations resulting from movement of said domains within said device.

Devices embodying the present invention are unlike known, commercially available Gunn effect devices, in that real-space electron transfer is possible in addition to, or instead of, k-space electron transfer. A further difference is that devices embodying the present invention have a substantially planar geometry, with electron transport occurring parallel to the semiconductor layers rather than perpendicular to the layers. Gunn domains therefore form in a very narrow and relatively high electron density region of the device. The planar geometry of the device of the present invention allows for more efficient cooling of the device, so that electron densities in the device are able to reach much higher levels before overheating becomes a problem than is the case for previously known vertical Gunn effect devices. This in turn permits the formation of domains that are very much shorter (narrower) than domains in vertical devices. This offers the possibility of very high frequency operation.

The planar geometry of devices embodying the present invention also means that such devices are well suited to monolithic integration.

The first electrode may be an anode contact, said anode contact extending from a first outer surface of the device down into one or more layers below said first outer surface.

The anode contact may be annealed.

Alternatively, the anode contact may connect solely with the upper layer.

The second electrode may be a cathode contact provided to an outer surface of the device.

The cathode contact may not have been annealed and may be an injection limited cathode contact.

The cathode may connect solely with the upper layer.

If at least one of the electrodes is located only on an outer surface of the device and does not contact any of the other layers, a plurality of devices with differing frequency ratings can be manufactured from a single wafer by varying the distances between respective electrodes.

The cathode contact may have been annealed.

The cathode and anode contacts may be ohmic contacts.

The carriers may be electrons and the negative resistance regime may then be produced by a transferred-electron effect.

Additionally, the negative resistance regime may be produced by a real-space transferred-electron effect.

An effective mass of the carriers may be alternately higher and lower in adjacent layers. Preferably, the device comprises at least three active layers wherein an effective mass of carriers in a middle layer is lower than an effective mass of carriers in either adjacent layer.

One of said layers may consist of GaAs and an adjacent layer or layers may consist of Al₍ₓ₎Ga₍₁₋ₓ₎As where 0<x<1.

One of said layers may consist of In₍ₓ₎Ga₍₁₋ₓ₎As, and an adjacent layer or layers may consist of Al₍ₓ₎Ga₍₁₋ₓ₎As where 0<x<1.

The Al₍ₓ₎Ga₍₁₋ₓ₎As layer or layers may include an n-type doped sub-layer. Preferably, the n-type doped sub-layer is delta-doped.

For the Al₍ₓ₎Ga₍₁₋ₓ₎As layers, x may be between 0.12 to 0.36, but is preferably between 0.19 to 0.25.

The semiconductor device may further comprise one or more additional electrodes disposed between the first and second electrode. The additional electrode may be solely in contact with the upper layer of the device. An additional electrode acts as a gate and may be used to control or select the frequency of the oscillating voltage as the location of domain creation can be controlled by placement of the additional electrode. Furthermore, an additional electrode encourages domain creation, resulting in a more efficient device.

The one or more additional electrodes may be provided on an outer surface of the device or may be provided in a recess in an outer layer of the device.

Preferably, the semiconducting layers are substantially planar.

The semiconductor layers may have alternately larger and smaller band gaps. Preferably, an effective mass of carriers in the layer or layers with the larger band gap is higher than an effective mass in the layer or layers with the smaller band gap.

Adjacent semiconductor layers may have alternately larger and smaller conduction band offsets. Preferably, an effective mass of carriers in a layer or layers with the larger conduction band offset is higher than an effective mass of carriers in a layer or layers with the smaller conduction band offset.

The term “offset” as used herein may be taken to refer to the relative energy offset of/from the lowest conduction band state.

Adjacent semiconductor layers may have alternately higher and lower conduction band minima. Preferably, an effective mass of carriers in the layer or layers with the higher conduction band minimum is higher than an effective mass in the layer or layers with the lower conduction band minimum.

Adjacent layers may have alternately higher and lower valence band positions. Preferably, the effective mass of carriers in the layer or layers with the higher valence band position is higher than the effective mass in the layer or layers with the valence band position.

The valence band position may be viewed as a bulk parameter for the material of individual layers, which can then be subtracted to determine the relative band alignment at a given heterojunction.

According to a further aspect of the present invention, there is provided a semiconductor device comprising a plurality of semiconducting layers arranged substantially parallel to a major surface, said layers having alternately larger and smaller conduction band offsets, a first layer being provided with an injection-limited cathode contact, the said layers being provided with an ohmic anode contact which extends from said major surface down into the layers under the first layer, said anode contact being spaced from the cathode contact in a direction parallel to said major surface, the said semiconducting layers being fabricated such that the carrier mobility in the layer or layers with the larger conduction band offset is lower than the carrier mobility in the layer or layers with the smaller conduction band offset, thereby causing or permitting an oscillating voltage to be generated across the device, when the contacts are suitably biased, said oscillating voltage being produced by means of a negative resistance regime by carriers traveling in a direction at least partly parallel to said semiconducting layers.

Embodiments of the invention will now be described, by way of example only, with reference to the accompanying schematic Figures, in which:—

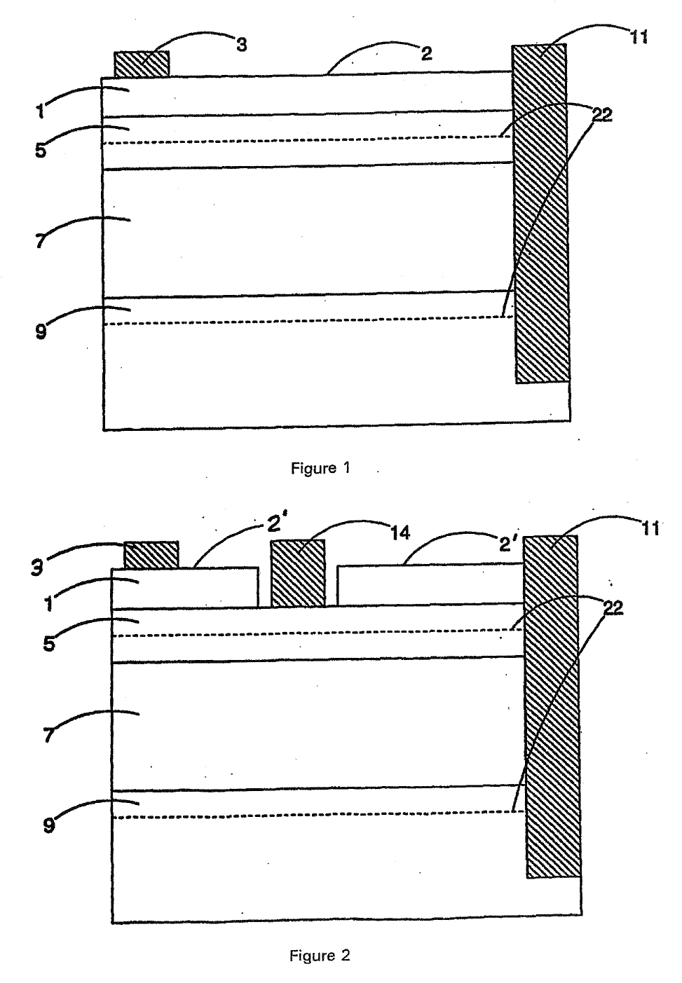

FIG. 1 shows a cross-section of a semiconductor device embodying the present invention;

FIG. 2 shows a cross-section of a further semiconductor device embodying the present invention;

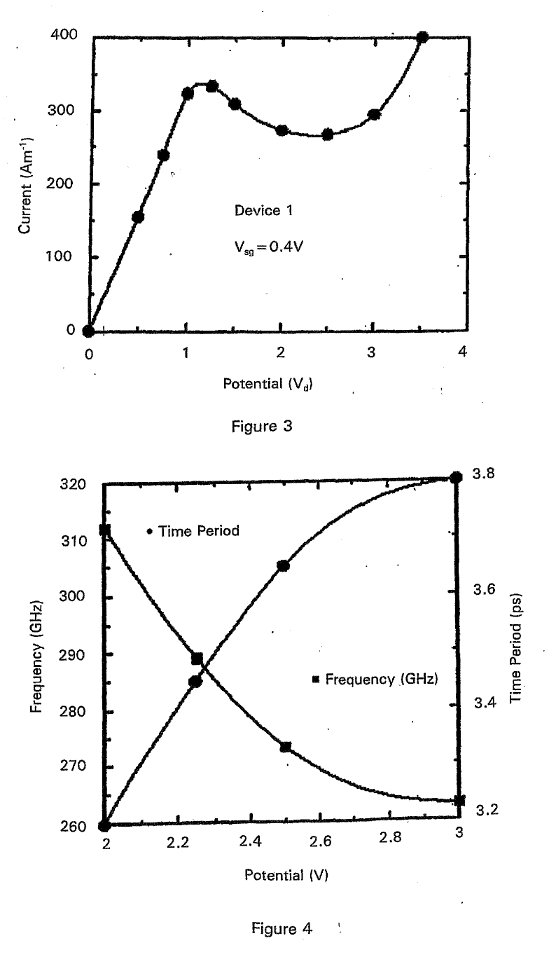

FIG. 3 shows computer simulated I-V characteristics of a further semiconductor device embodying the present invention;

FIG. 4 shows computer simulated frequency dependence and domain transit time as a function of drain potential for the device for which results are shown in FIG. 3;

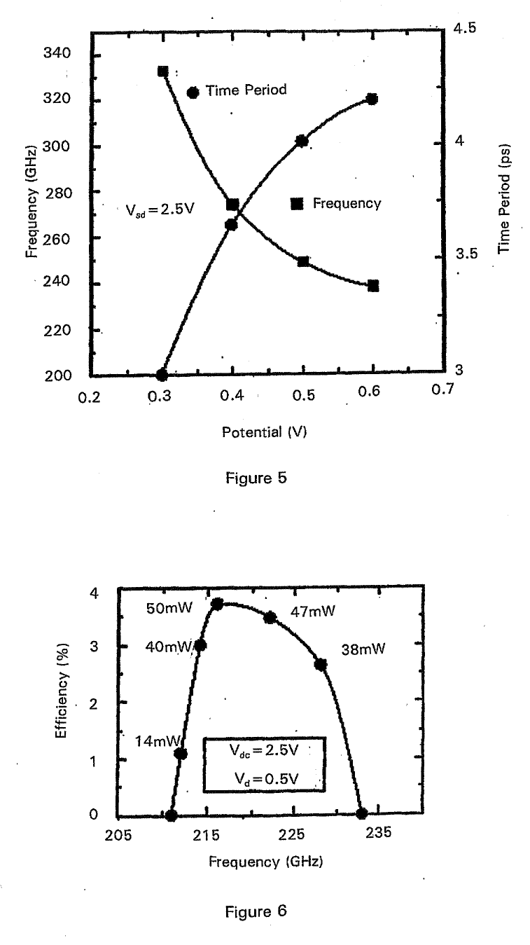

FIG. 5 shows computer simulated frequency dependence and domain transit time as a function of gate potential for the device for which results are shown in FIGS. 3 and 4;

FIG. 6 shows the efficiency and power of the device for which results are shown in FIGS. 2 to 5 as a function of RF potential;

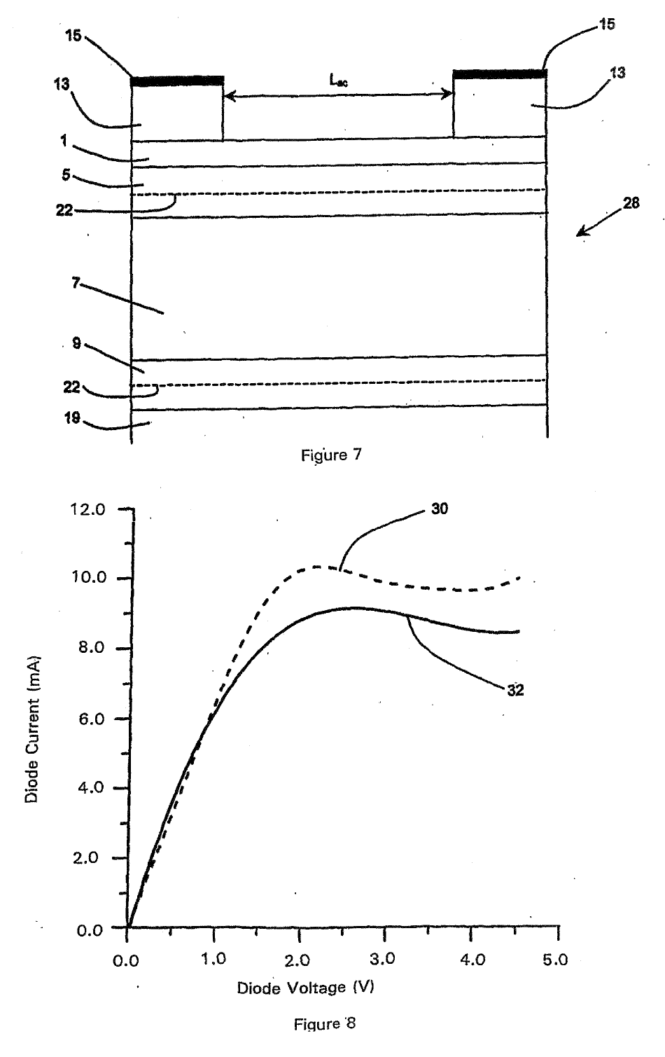

FIG. 7 shows a cross-section of a further semiconductor device embodying the invention; and

FIG. 8 illustrates an I-V graph for the device of FIG. 7.

In the Figures, components common to the different embodiments have common reference numerals.

A first semiconductor device embodying the present invention is shown in FIG. 1. The device comprises a plurality of substantially planar semiconducting layers 1, 5, 7, 9 arranged parallel to a major surface 2, the layers having alternately larger and smaller band gaps, providing alternately larger and smaller conduction band offsets. The upper (top) layer 1 is provided with an injection-limited cathode contact 3. The layers 1, 5, 7, 9 are provided with an ohmic anode contact 11 which extends from the major surface down into the lower layers. The anode contact is spaced from the cathode contact in a direction parallel to the major surface.

The semiconducting layers are deposited on to a semi-insulating GaAs substrate (not shown), which may be thinned after fabrication if desired to reduce thermal resistance. The layers are lattice matched to the dimensions of the GaAs substrate lattice in the conventional manner. The semiconductor device is preferably fabricated using molecular beam epitaxy (MBE), although other techniques can be employed.

The upper semiconducting layer 1 is 15 nm thick, and is heavily doped n-type GaAs, typically having a carrier concentration of 3.5×10²⁴ m⁻³, an electron mobility of about 8×10³ cm²V⁻¹ s⁻¹=0.8 m²V⁻¹ s⁻¹ and a direct band gap of 1.42 eV. This layer is deposited on top of a further layer 5 which is 20 nm thick and made from Al₍ₓ₎Ga₍₁₋ₓ₎As, where x=0.22. This material has an electron mobility of approximately 4×10³ cm²V⁻¹ s⁻¹=0.4 m²V⁻¹ s⁻¹, and a direct band gap of 1.7 eV. Layer 5 is delta-doped n-type with a layer of dopant 22 10 nm from the interfaces, providing a doping density of 8×10¹⁵ m⁻². Layer 7 comprises a 50 nm thick layer of undoped GaAs, having an electron mobility of approximately 8×10³ cm²V⁻¹ s⁻¹=0.8 m²V⁻¹ s⁻¹ and a direct band gap of 1.42 eV. Finally, layer 9 comprises a layer of AlGaAs more than 20 nm thick. Layer 9 is n-type delta doped as layer 5 10 nm from the interface, and is carried by the GaAs substrate (not shown).

The semiconducting layers described above and shown in FIG. 1 have been designed and arranged such that the electron mobility in the layer or layers with the larger band gap 5, 9 is lower than the electron mobility in the layer or layers with the smaller band gap 1, 7, thereby causing or permitting an oscillating voltage to be generated across the device, when the contacts are suitably biased, the oscillating voltage being produced by means of a transferred-electron effect by electrons traveling in a direction at least partly parallel to the planar layers. It is possible for this device structure to exhibit either real-space electron transfer or k-space electron transfer to provide a negative differential resistance leading to oscillation, the exact mechanism depending upon the electric fields used.

In the device shown in FIG. 1, the spacing between the cathode 3 and the anode 11 (i.e. the channel length) is 1.3 μm, although smaller channel lengths are preferred for higher frequency operation. The device width might typically be of the order of one or two mm. Devices having different impedances can be made using different device widths.

Although in the embodiment shown in FIG. 1 the value of x is 0.22, other values of x may be chosen. The value of x preferably lies in the range 0.1 to 0.4, more preferably in the ranges 0.12 to 0.36 or 0.19 to 0.25.

FIG. 2 shows a cross-sectional view of a second semiconductor device embodying the present invention. This device is substantially the same in structure as the device of FIG. 1, except that the device of FIG. 2 has a three terminal “HEMT-like” structure, being provided with an additional “gate” electrode 14 in a gap in the upper semiconducting layer 1, between the cathode contact 3 and the anode contact 11. However, this gap in the upper layer 1 is not necessary. In a further embodiment, the “gate” electrode is provided on the upper surface of the outer layer 1. Further additional contacts of this type may be provided to give a device having a plurality of selectable different channel lengths, which can therefore oscillate at a plurality of selected different frequencies in use. Small geometry devices of this type may require electron beam lithography or deep UV lithography for electrode patterning. In the device shown in FIG. 2, the gap in the upper semiconducting layer 1 can be obtained by wet chemical etching using a (1:1:10 H₂SO₄:H₂O₂:H₂O₂) solution to remove a section of the layer 1, thereby creating the major surface 2′. The matching of the edge of the gate electrode 14 to the side of the gap in layer 1 may be tighter (ie the edge of the gate electrode 14 and the edge of the gap may be closer) than shown in FIG. 2, in order to reduce problems with oxidation of the revealed AlGaAs layer under the gate electrode 14.

In the embodiments described in FIGS. 1 and 2, an annealed contact 11 is used at the drain end of the device, making a low resistance ohmic connection which extends into the device, allowing electrons to be removed from the device easily. The annealing of this contact causes the contact to extend downwards through the semiconducting layers, as shown in FIGS. 1 and 2. An example of how to make an annealed ohmic contact is described in the paper by John Biddle at http://www.eduprograms.deas.harvard.edu/reu03_papers/Biddle.J.FinReport03.pdf. This method employs an Ni/Au/Ge structure annealed between 400° C. and 425° C. for 60 to 80 seconds. If deeper contacts are required, the annealing step can be performed at a higher temperature and/or for a longer time.

A non-annealed cathode contact 3 is provided at the source end of the device, deposited after the anode contact 11 has been annealed. This contact can be made to have a low resistance by using a highly-doped region adjacent the metal (making the Schottky barrier very thin, allowing quantum mechanical tunneling).

The “gate” contact 14 of the device shown in FIG. 2 is also non-annealed. In embodiments having more than one such “gate” contact, the additional “gate” contacts will also be non-annealed.

The lack of annealing of the cathode contact 3 means the layer structure underneath the contact is preserved, allowing the electrons to accumulate/traverse along the bottom of the top GaAs layer 1 (forced downwards by the field from the trapped charge at the top surface of the device), accelerated by the field from the source-drain biasing. A Gunn domain then forms part way along the device, as electrons shift into the top AlGaAs layer 5.

In the device shown in FIG. 1, the electrons travel in a “u” shaped trajectory, first downwards over the AlGaAs barrier, then along the device, then into the annealed contact region and up and out at the drain or anode contact 11. The downwards part could be considered to be over an ‘injector’ region as found in vertical Gunn diodes. However, the ‘injector’ is simply a square barrier (uniform-Al-content AlGaAs), and is also fed with electrons having a range of energies according to the distance along the device.

Although the cathodes 3 at the source end of the devices shown in FIGS. 1 and 2 are non-annealed, further embodiments of the present invention comprise an annealed source contact. Further embodiments have the metal portion of all electrodes annealed. In particular, a further embodiment is similar to the “gated” device of FIG. 2, but has an annealed source contact.

Delta-doping is used in the layers in the above described embodiments. However, devices can also be made with graded doping profiles as an alternative. Methods of delta-doping of semiconductors are described in “Delta-doping of Semi-conductors” edited by E. F. Schubert, published by Cambridge University Press (1996).

The doping and/or dimensions (preferably the height) of layer 1 of the device shown in FIGS. 1 and 2 is set such that the charge in the layer balances the depletion from the surface charge, such that the electrostatic potential going down through the lower layers is comparatively flat (as opposed to being sloped down such that charge accumulates overly near the base of the channel/lower barrier or at the top of the channel and in the lower part of the doped GaAs layer). This improves the likelihood of domain (dipole) formation, the likelihood of their utilising/filling the entire barrier/channel/barrier region (improving current swing) and successfully transiting to and exiting the drain contact. Therefore, layer 1 assists in providing an environment conducive to the formation of charge domains, but does not play an active role in the formation of these domains (in the sense of donating or receiving charge carriers).

For a particular composition of layer 1, the height is chosen so that the charge in the layer balances the depletion in the layer due to the surface charge in use of the device.

Other methods could be employed to achieve accurate negation of surface charge and/or extra mobile charge, in order that the potential down the device is maintained as ‘flat’ as possible such as providing an upper (outer) layer 1 comprising a number of layers of differing levels of doping so that a lower doped layer is closer to the surface exposed to etching during manufacture. This provides for a greater degree of tolerance to over- or under-etching.

In the devices shown in both FIG. 1 and FIG. 2 computer modeling has shown that Gunn domains form quite readily with relatively little fine tuning to the device parameters. However, in the case of the device shown in FIG. 1, some care has to be taken in obtaining the optimum potential well depth, as too high a discontinuity in energy gap between layers would tend to trap electrons at the anode, thereby extinguishing domain oscillations. The presence of the annealed anode contact mitigates this problem.

The concept of utilizing a HEMT-like structure, as in the device shown in FIG. 2, allows the high mobility of the well to be utilized free of ionized impurity scattering, which is so detrimental to the NDR characteristics of the material at these higher carrier densities. Meanwhile, the spatial separation of negative and positive charge does not seem to interfere or disturb the dipole form, though the negative charge has a transverse nature.

The range of potentials over which two terminal devices work is not large, setting limits on the power output of such devices. This situation can be alleviated somewhat in three terminal devices, where the presence of the additional (gate) electrode assists domain nucleation at lower potentials.

FIG. 3 shows computer simulated I-V characteristics of a device embodying the present invention, at a gate potential of 0.4V (1.2V including the Schottky barrier). The device for which the results are simulated is a three terminal HEMT-like structure having a 12 nm InGaAs well sandwiched between AlGaAs with delta doped n layers 2 nm from the edge of the well in the AlGaAs. The device has a drain-gate length (distance from “gate” to anode) of 0.75 μm and a source-gate length (distance from cathode to “gate”) of 0.2 μm. All distances in respect of electrodes quoted herein refer to the shortest distance between the respective edges of respective electrodes.

The NDR region is caused by the presence of strong dipoles which grow in amplitude with increasing drain potential, thus reducing the current. An important feature here is that, unlike in normal Gunn devices, the NDR behaviour of the material system which causes the formation of the dipoles is caused by the transfer of electrons out of the InGaAs region into an adjacent AlGaAs region.

The location of electrons in the low field region are confined for the most part to the potential well in the InGaAs Gamma valley, and in the high field region they are located mostly in the AlGaAs “heavy” valleys.

FIGS. 4 and 5 show the computer simulated frequency dependence and the domain transit time as a function of drain and gate potential respectively for the same device as FIG. 3. The dependence of frequency on gate potential is to be expected from the alterations in the gate potential alone, but it should also be noted that the gate acts as a natural nucleation point for a domain.

From FIGS. 3 to 5 it can be seen that there is a relatively narrow window of less than about 1.5 V over which the device will form dipoles without breaking down, and this will set limitations on the power output of the device at a gate potential of 0.4 V. The drain potential range can, however, be increased a little by increasing the gate potential to assist domain nucleation.

FIG. 6 shows the efficiency and power of the device as a function of RF potential for

V=2.5+0.5 sin(αt)V.

FIG. 7 illustrates a semi-conductor device 28 according to a further embodiment. The upper layer 1 is 15 nm of highly doped n-GaAs followed by layer 5, 20 nm thick, of undoped Al_{0.23}Ga_{0.77}As with δ-doping 22 in the middle having an areal density of 8×10¹¹ cm⁻².

The layer 7 is 50 nm thick and comprises GaAs. Beneath the layer 7 there is a further 20 nm thick AlGaAs layer, layer 9, that is also δ-doped on the GaAs substrate 19. The layer 7 has an electron charge density of ˜10⁻⁷ cm⁻³. Multiple graded layers of GaAs/InGaAs layers 13 are grown above the device. These layers are subsequently removed from the active device area as described below.

The as-grown wafers were cleaved into 15 mm×15 mm samples. Device mesas were made by electron beam direct write into UV-III resist and etching in 1:1:10 of H₂O₂:H₂O:H₂SO₄ solution for 90 seconds at an etch rate of 60 nm/s. Ohmic contact patterns (not shown) were made by electron beam direct write into a bilayer of poly methyl(methacrylate) (PMMA) resist (high molecular weight on top of low molecular weight). Prior to contact metal deposition, the patterned sample was oxygen plasma cleaned using 100 W for 60 seconds. The contact areas were then de-oxidised in 1:4 HCl:H₂O for 30 seconds followed by 1:10 NH₄OH:H₂O for 30 seconds.

The sample was then rinsed in water before drying. N-type contacts 15 were made by sequential deposition of 20 nm Pd, 50 nm Ge, 10 nm Au, 50 nm Pd and 150 nm Au. The final layer of gold helps to give a surface suitable for device probing. After lift-off, the samples were annealed at 400° C. for 60 seconds in an optically heated rapid thermal annealer. The typical contact resistivity after processing was 5×10⁻⁶Ω-cm².

The final step in the fabrication of the devices was the removal of the unwanted GaAs/InGaAs contact layers 13 above the active region. This was facilitated using an Al_{0.8}Ga_{0.2}As etch stop layer that was inserted during wafer growth. The samples were etched in 3:1 citric acid:H₂O₂ (50% w/w citric acid) solution for 20 seconds. The contact layers 13 assist in creating a current path between the electrodes 15 and the layer 1 of the device and as such may be considered to be part of the electrodes.

The device of FIG. 7 has a anode-cathode distance (L_{ac}), of 1.3 μm and a width of 60 μm. FIG. 8 illustrates an I-V graph for the device of FIG. 7 where dashed line 30 represents the results of a direct current applied to the device 28, whereas solid line 32 represents the results of a pulsed current applied to device 28. As is apparent from FIG. 8, an applied pulsed current results in a greater current. The negative resistance differential is illustrated by the portions of lines 30 and 32 having negative slope.

During operation of the device 28, a bias in the range of 3.5V to 4.5V was applied and oscillations having frequencies of 35 to 108 GHz were observed.

Although the embodiments of FIGS. 1, 2 and 7 have employed GaAs—AlGaAs semiconductor heterostructures, alternative structures are also possible. In particular, a further type of device has a layer of InGaAs sandwiched between layers of AlGaAs.

In one such device, a 12 nm InGaAs well is sandwiched between AlGaAs layers 25 nm thick, with delta doped n-type layers located 10 nm from the interfaces at the edge of the well in the AlGaAs. The device has a drain-gate length of 0.75 μm, and source-gate length of 0.2 μm.

The NDR behaviour of the AlGaAs—InGaAs device is dominated by transfer of electrons out of the higher mobility InGaAs layer into the lower mobility AlGaAs bulk, as found by Glisson, Hauser et al. (J. Appl. Phys. Vol 51, pp 5445-5449 (1980)). According to this paper, the maximum mean electron density inside the well (under very low field conditions) is about 6×10¹⁷ cm⁻³.

Although the above embodiments have employed III-V compound semiconductor heterostructures, devices embodying the present invention can also be made using Si—Ge heterostructures to fabricate devices which work in a similar way, because the higher band gap material (i.e. Si) has a lower carrier mobility. NDR in Si—Ge layers has been reported by S J Wang and S L Wu, Proc. Nat. Sci. Council, Vol 22, No. 3, ROC, part A, Physical Science and Engineering, pp 425-430 (1998). Devices according to the present invention may also be fabricated using group III nitride and/or phosphide layers. It is however likely that in materials where k-space electron transfer is absent, Gunn domain formation will be more difficult.

In the aforementioned embodiments, a semiconductor device for generating an oscillating voltage has been described which comprises several layers arranged in a quantum-well structure, in which the layers have alternately larger and smaller band gaps (or conduction band offsets). The upper layer may have a Schottky-barrier cathode contact, and the lower layers may have an annealed ohmic anode contact which extends down from the upper layer. Alternatively, both the cathode and the anode may be annealed. The layers are arranged such that the carrier mobility in the layers with the larger band gap or conduction band offset is lower than the carrier mobility in the layers with the smaller band gap or conduction band offset. Carriers traveling parallel to the layers generate an oscillating voltage by means of a transferred-electron effect.

1.-53. (canceled)

54. A semiconductor device comprising at least a first and a second electrode and a plurality of semiconductor layers, said layers being arranged substantially parallel to one another with adjacent layers comprising different semiconductor materials so that the device produces voltage oscillations due to a negative differential resistivity on application of a potential difference across said electrodes, said electrodes being attached to said device spaced from one another in a direction parallel to said layers, said device further comprising an upper semiconductor layer wherein a composition and/or height of said upper layer is predetermined so that a charge therein balances a depletion from a surface charge of the upper layer on application of said potential difference.

55. A semiconductor device according to claim 54 wherein the semiconductor material of said upper layer resists oxidation.

56. A semiconductor device according to claim 54 wherein the degree or manner of doping of the upper layer is predetermined.

57. A semiconductor device according to claim 54 wherein said upper layer is composed of n-GaAs.

58. A semiconductor device according to claim 54 wherein the upper layer is composed of a plurality of sub-layers of differing doping levels, said sub-layers being disposed so that a lower doped layer is closer to a surface of the device than a higher doped layer.

59. A semiconductor device according to claim 54 wherein said upper layer is inactive for not contributing or receiving charge carriers in the formation of negative differential.

60. A semiconductor device according to claim 54 wherein a composition and/or height of said upper semiconductor layer is chosen so that an electrostatic potential through said layers of said device is substantially flat.

61. A semiconductor device according to claim 54 wherein a composition of said semiconductor layers is chosen so that, on application of said potential difference, domains spanning more than one layer form in said device, said voltage oscillations resulting from movement of said domains within said device.

62. A semiconductor device according to claim 54 wherein said first electrode is an anode contact, said anode contact extending from a first outer surface of the device down into one or more layers below said first outer surface.

63. A semiconductor device according to claim 62 wherein the anode contact has been annealed.

64. A semiconductor device according to claim 63 wherein the anode contact is an ohmic contact.

65. A semiconductor device according to claim 54 wherein said second electrode is a cathode contact, said cathode contact being provided on an outer surface of the device.

66. A semiconductor device according to claim 65 wherein the cathode contact has not been annealed.

67. A semiconductor device according to claim 66 wherein the cathode is an injection limited cathode contact.

68. A semiconductor device according to claim 65 wherein the cathode connects solely with the upper layer.

69. A semiconductor device according to claim 54 wherein the charge carriers are electrons and the negative differential resistivity is produced by a transferred-electron effect.

70. A semiconductor device according to claim 69 wherein the transferred-electron effect is a real-space transferred-electron effect is a real-space transferred-electron effect is a real-space transferred-electron effect.

71. A semiconductor device according to claim 59 wherein one of said layers consists of one of GaAs and In₍ₓ₎Ga₍₁₋ₓ₎As, and an adjacent layer or layers consist of Al₍ₓ₎Ga₍₁₋ₓ₎As where 0<x<1.

72. A semiconductor device according to claim 71 wherein the Al₍ₓ₎Ga₍₁₋ₓ₎As layer or layers include an n-type doped sub-layer.

73. A semiconductor device according to claim 72 wherein the n-type doped sub-layer is delta-doped.

74. A semiconductor device according to claim 73 wherein, for Al₍ₓ₎Ga₍₁₋ₓ₎As, x=0.12 to 0.36.

75. A semiconductor device according to claim 74 wherein, Al₍ₓ₎Ga₍₁₋ₓ₎As, x=0-19 to 0.25.

76. A semiconductor device according to claim 54 further comprising one more additional electrodes disposed between the first and second electrodes.

77. A semiconductor device according to claim 76 wherein each of the one or more additional electrodes is provided in a recess in an outer layer of the device.

78. A semiconductor device according to claim 54 wherein the layers have alternately larger and smaller band gaps or conduction band offsets.

79. A semiconductor device according to claim 78 wherein an effective mass of carriers in the layer or layers with the larger band gap or conduction band offset is higher than an effective mass in the layer or layers with the smaller band gap or conduction band offset.

80. A semiconductor device according to claim 54 wherein adjacent layers have alternately higher and lower conduction band minima.

81. A semiconductor device according to claim 80 wherein an effective mass of carriers in the layer or layers with the higher conduction band minimum is higher than an effective mass in the layer or layers with the lower conduction band minimum.

82. A semiconductor device according to claim 54 wherein adjacent layers have alternately higher and lower valence band positions.

83. A semiconductor device according to claim 82 wherein the effective mass of carriers in the layer or layers with the higher valence band position is higher than the effective mass in the layer or layers with the valence band position.

84. A semiconductor device comprising a plurality of semiconducting layers arranged substantially parallel to a major surface, said layers having alternately larger and smaller conduction band offsets, a first layer being provided with an injection-limited cathode contact, the said layers being provided with an ohmic anode contact which extends from said major surface down into the layers under the first layer, said anode contact being spaced from the cathode contact in a direction parallel to said major surface, the said semiconducting layers being fabricated such that the carrier mobility in the layer or layers with the larger conduction band offset is lower than the carrier mobility in the layer or layers with the smaller conduction band offset, thereby causing or permitting an oscillating voltage to be generated across the device, when the contacts are suitably biased, said oscillating voltage being produced by means of a negative resistance regime by carriers travelling in a direction at least partly parallel to said semiconducting layers.

85. A method of manufacturing a semiconductor device comprising the steps of:
providing a plurality of semiconductor layers with adjacent layers comprising different semiconductor materials;
providing at least two electrodes attached to said plurality of layers spaced from one another in a direction parallel to said layers;
choosing an upper layer of said plurality of layers so that a charge therein balances a depletion from a surface charge of the upper layer on application of a potential difference across said electrodes.

86. A method of manufacturing a semiconductor device according to claim 85 wherein said plurality of semiconductor layers are arranged so that the device produces voltage oscillations due to a negative differential resistivity on application of a potential difference across said electrodes.

87. A method of manufacturing a semiconductor device according to claim 86 wherein said step of choosing an upper layer comprises the step of choosing a height of said upper layer in dependence upon a composition of said upper layer.
